(19) United States
(12) Patent Application Publication
(10) Pub. No.: US 2026/0130257 A1
(43) Pub. Date: May 7, 2026

(54) SEMICONDUCTOR PACKAGE AND SEMICONDUCTOR PACKAGE REPROCESSING METHOD

(71) Applicant: SAMSUNG ELECTRONICS CO., LTD., Suwon-si (KR)

(72) Inventors: Taeksoo Shin, Suwon-si (KR); Seungboo Jung, Suwon-si (KR); Jaejun Yoon, Suwon-si (KR); Yeonju Go, Suwon-si (KR); Kyongbin Ham, Suwon-si (KR)

(73) Assignees: SAMSUNG ELECTRONICS CO., LTD., Suwon-si (KR); RESEARCH & BUSINESS FOUNDATION SUNGKYUNKWAN UNIVERSITY, Suwon-si (KR)

(21) Appl. No.: 19/377,939

(22) Filed: Nov. 3, 2025

(30) Foreign Application Priority Data
Nov. 5, 2024 (KR) 10-2024-0155674
Dec. 30, 2024 (KR) 10-2024-0201200

(51) Int. Cl. H01L 23/00

(52) U.S. Cl. CPC H10W 72/20; H10W 72/90; H10W 72/235; H10W 72/252; H10W 72/952; H10W 90/724

(57) ABSTRACT

A semiconductor package including: a semiconductor device; a first connection pad on one surface of the semiconductor device; a connection terminal at one end of the first connection pad; and a second connection pad in contact with the connection terminal, wherein the connection terminal is between the first connection pad and the second connection pad, wherein the connection terminal includes a first terminal region and a second terminal region, wherein the first terminal region is at least partially surrounded by the second terminal region, and wherein the second terminal region includes an oxidized metal, and a thickness of the second terminal region varies.

### CROSS-REFERENCE TO RELATED APPLICATION

This application is based on and claims priority under 35 U.S.C. § 119 to Korean Patent Application Nos. 10-2024-0155674, filed on Nov. 5, 2024, and 10-2024-0201200, filed on Dec. 30, 2024, in the Korean Intellectual Property Office, the disclosures of which are incorporated by reference herein in their entireties.

### BACKGROUND

### 1. Field

Some embodiments of the present disclosure relate to a semiconductor package and a semiconductor package reprocessing method, and more particularly, to a semiconductor package and a semiconductor package reprocessing method, wherein a solder ball provided in the semiconductor package is etched.

### 2. Brief Description of Background Art

When a semiconductor device is mounted on a substrate or another semiconductor device, an electrical connection may be established by connection terminals. For example, the connection terminals may include solder balls. Oxide layers may be formed on surfaces of the solder balls. When the oxide layers of the solder balls are formed on the surfaces thereof, the solder balls are less likely to wet pads when in contact with the pads. When the solder ball does not wet the pad, resistance in an electrical connection may be excessively high, or the electrical connection may not be established. That is, the oxide layers formed on the solder balls may lead to poor electrical connections in semiconductor devices. There is a need for a solution to prevent non-wetting caused by the oxide layers on the solder balls or to resolve poor electrical connections in semiconductor packages caused by the non-wetting.

### SUMMARY

According to embodiments of the present disclosure, a semiconductor package may be provided, wherein an oxide layer of the semiconductor package is selectively etched to prevent or eliminate an electrical connection failure caused by the oxide layer of a solder ball of the semiconductor package, and the semiconductor package having the non-wetting failure is reprocessed.

According to some embodiments of the present disclosure, a semiconductor package may include: a semiconductor device; a first connection pad on one surface of the semiconductor device; a connection terminal at one end of the first connection pad; and a second connection pad in contact with the connection terminal, wherein the connection terminal is between the first connection pad and the second connection pad, wherein the connection terminal includes a first terminal region and a second terminal region, wherein the first terminal region is at least partially surrounded by the second terminal region, and wherein the second terminal region includes an oxidized metal, and a thickness of the second terminal region varies.

According to some embodiments of the present disclosure, a semiconductor package may include: a semiconductor device; a first connection pad on one surface of the semiconductor device; and a connection terminal at one end of the first connection pad, wherein the connection terminal includes a first terminal region and a second terminal region, wherein the first terminal region is at least partially surrounded by the second terminal region, and wherein the second terminal region includes an oxidized metal, and a thickness of the second terminal region varies.

According to some embodiments of the present disclosure, a semiconductor package may include: a semiconductor device; a first connection pad on one surface of the semiconductor device; a connection terminal at one end of the first connection pad; and a second connection pad in contact with the connection terminal, wherein the connection terminal includes a solder ball, wherein the connection terminal is between the first connection pad and the second connection pad, wherein the solder ball includes a first terminal region and a second terminal region, wherein the first terminal region is at least partially surrounded by the second terminal region, wherein the second terminal region includes an oxidized metal, and a thickness of the second terminal region varies, wherein the oxidized metal in the second terminal region includes tin oxide, wherein the first terminal region includes at least one from among tin, silver, and copper, wherein the first terminal region includes a terminal metal layer, and the terminal metal layer is in contact with the second connection pad and the second terminal region, wherein the terminal metal layer includes at least one from among a nickel-tin (Ni—Sn) alloy, a copper-tin (Cu—Sn) alloy, a gold-tin (Au—Sn) alloy, and a palladium-tin (Pd—Sn) alloy, wherein the thickness of the second terminal region at a first point of the second terminal region is greater than the thickness of the second terminal region at a second point of the second terminal region, wherein the thickness of the second terminal region at the second point of the second terminal region is greater than the thickness of the second terminal region at a third point of the second terminal region, wherein the thickness of the second terminal region at the first point of the second terminal region is in a range of 90 Å to 190 Å, wherein the thickness of the second terminal region at the second point of the second terminal region is in a range of 50 Å to 120 Å, wherein the thickness of the second terminal region at the third point of the second terminal region is in a range of 0 Å to 70 Å, wherein a distance from the first connection pad to the second point is farther than a distance from the first connection pad to the first point, wherein a distance from the first connection pad to the third point is farther than the distance from the first connection pad to the second point, wherein a thickness of a thickest portion of the second terminal region is 3 times to 10 times a thickness of a thinnest portion of the second terminal region, wherein the first terminal region is in contact with a portion of the first connection pad, the second terminal region is in contact with another portion of the first connection pad, the first terminal region is in contact with a portion of the second connection pad, and the second terminal region is in contact with another portion of the second connection pad, wherein the first connection pad includes a first pad metal layer and a second pad metal layer, wherein the first terminal region is in contact with the first pad metal layer, and the second terminal region is in contact with the first pad metal layer, and wherein the first pad metal layer includes at least one from gold (Au), nickel (Ni), tin (Sn), lead (Pb), and silver (Ag).

According to some embodiments of the present disclosure, a semiconductor package reprocessing method may include: identifying whether an oxide layer thickness of a solder ball of a semiconductor device is within a normal range; partially etching the oxide layer of the solder ball based on determining that the oxide layer thickness is not within the normal range; and mounting the semiconductor device, wherein the oxide layer includes tin oxide, and an amount of the oxide layer being etched increases with increasing distance from the semiconductor device.

In the partially etching of the oxide layer, a thickness of a remaining oxide layer may decrease with increasing distance from the semiconductor device.

In the mounting of the semiconductor device, the oxide layer in a region in which the solder ball is in contact with a pad may have a thickness less than or equal to 70 Å.

In the partially etching of the oxide layer, an etching solution containing NH₄F and HF may be used.

As a time for which etching is performed by an etching solution increases, an amount of the oxide layer being etched may increase.

In the partially etching of the oxide layer, with respect to a thickness the oxide layer remaining after etching, the thickness of the oxide layer at a first point may be greater than the thickness of the oxide layer at a second point, and the thickness of the oxide layer at the second point may be greater than the thickness of the oxide layer at a third point, wherein the first point of the oxide layer is adjacent to the semiconductor device, the second point of the oxide layer corresponds to a midpoint of a height of the solder ball, and the third point of the oxide layer is farther than the first point and the second point from the semiconductor device.

In the partially etching of the oxide layer of the solder ball, the etching may be selectively performed on the oxide layer of the solder ball.

The identifying of whether the oxide layer thickness is within the normal range may include determining whether a time that has elapsed since the solder ball was provided on the semiconductor device is greater than or equal to a first reference time.

According to some embodiments of the present disclosure, a semiconductor package reprocessing method may include: identifying a non-wetting failure in a semiconductor device; partially etching the oxide layer of the solder ball based on identifying the non-wetting failure of the semiconductor device; and mounting the semiconductor device, wherein the oxide layer includes tin oxide, and an amount of the oxide layer being etched increases with increasing distance from the semiconductor device.

The identifying of the non-wetting failure in the semiconductor device may include measuring electrical characteristics of the semiconductor device

Aspects of embodiments of the present disclosure are not limited to the aspects mentioned above, and other aspects not described above will be clearly understood by those skilled in the art from the following description.

### BRIEF DESCRIPTION OF DRAWINGS

Embodiments will be more clearly understood from the following detailed description taken in conjunction with the accompanying drawings in which:

FIG. 1A is a cross-sectional view of a semiconductor package;

FIG. 1B is an enlarged cross-sectional view showing a region in the semiconductor package of FIG. 1A;

FIG. 2 is a cross-sectional view showing that the semiconductor package of FIGS. 1A and 1B is separated from a substrate;

FIG. 3A is a schematic perspective view showing that a connection terminal of a semiconductor package separated from a substrate is etched;

FIG. 3B is an enlarged cross-sectional view of a region of FIG. 3A, showing a change in a connection terminal during an etching process;

FIG. 4 is a cross-sectional view showing that a semiconductor package that has undergone an etching process of FIGS. 3A and 3B is mounted on a substrate;

FIG. 5A is a cross-sectional view of a semiconductor package according to embodiments;

FIG. 5B is an enlarged cross-sectional view showing a region in the semiconductor package of FIG. 5A;

FIG. 6A is a flowchart showing a semiconductor package reprocessing method according to embodiments;

FIG. 6B is a flowchart showing a semiconductor package reprocessing method according to embodiments;

FIG. 7 is a flowchart showing a semiconductor package reprocessing method according to embodiments;

FIG. 8 shows the relationship between the thickness of an oxide layer and the time for which the oxide layer has been left in a high-temperature, high-humidity environment;

FIG. 9 shows the relationship between the thickness of the oxide layer and the etching time;

FIG. 10 is a graph showing, as shear strength, the relationship between the bonding strength of solder balls and the time for which the solder balls have been left in a high-temperature, high-humidity environment;

FIG. 11 is a graph showing the relationship between the resistance of a solder ball and a connection pad and the time for which the solder ball has been left in a high-temperature, high-humidity environment;

FIG. 12A is a cross-sectional view of a semiconductor package according to embodiments; and

FIG. 12B is an enlarged cross-sectional view showing a region in the semiconductor package of FIG. 12A.

### DETAILED DESCRIPTION

Hereinafter, non-limiting example embodiments of the present disclosure are described in detail with reference to the accompanying drawings.

The example embodiments of the present disclosure are provided to more fully describe the present disclosure to those skilled in the art. The example embodiments may be modified in many different forms, and the scope of the present disclosure is not limited to the example embodiments. Rather, these example embodiments are provided so that the present disclosure will be thorough and complete to those skilled in the art. Also, in the drawings, the thickness and size of each layer may be exaggerated for convenience and clarity of illustration.

As used herein, a first direction may be an X direction and a second direction may be a Y direction. The first direction and the second direction may be perpendicular to each other. A third direction may be a Z direction, and the third direction may be perpendicular to both the first direction and the second direction. A horizontal plane or a plane may be an X-Y plane. An upper surface of a specific object may be a surface located in the positive third direction with respect to the specific object and a lower surface of a specific object may be a surface located in the negative third direction with respect to the specific object.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

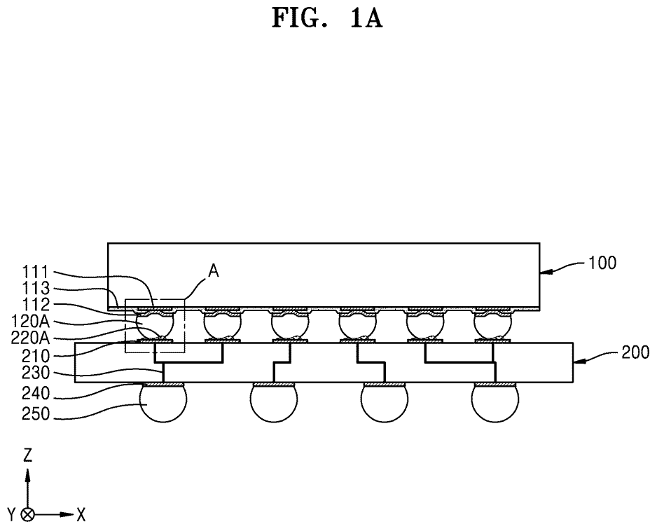

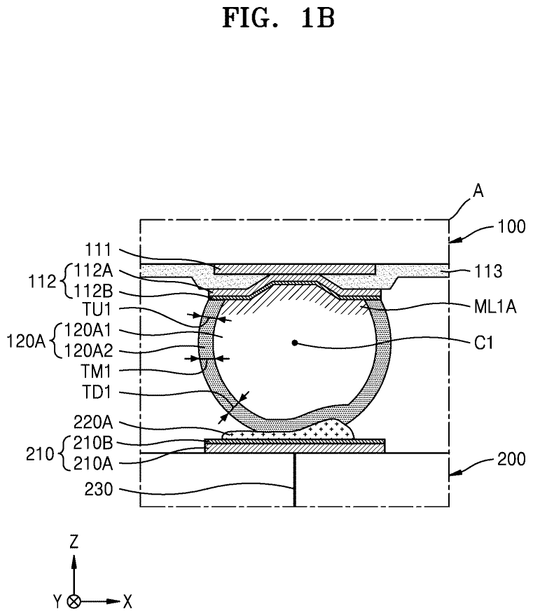

FIG. 1A is a cross-sectional view of a semiconductor package. FIG. 1B is an enlarged cross-sectional view showing a region A in the semiconductor package of FIG. 1A. More specifically, FIG. 1A illustrates that a semiconductor package 100 is mounted on a substrate 200 in a state in which a first connection terminal 120A does not wet a connection material layer 220A.

Referring to FIG. 1A, the semiconductor package 100 may be mounted on the substrate 200. The semiconductor package 100 may include, on one surface thereof, a first connection pad 112, a second connection pad 111 in contact with one surface of the first connection pad 112, an insulating layer 113 provided on the lower surface of the semiconductor package 100 and partially covering the second connection pad 111, and the first connection terminal 120A provided on the lower surface of the first connection pad 112. The substrate 200 may include, on the upper surface thereof, a third connection pad 210, and the connection material layer 220A may be disposed on the third connection pad 210. A fourth connection pad 240 may be provided on the lower surface of the substrate 200, and an external connection terminal 250 may be provided on the fourth connection pad 240. The substrate 200 may be connected to external electronic devices, such as printed circuit boards, via the external connection terminal 250.

The substrate 200 may include a substrate wire 230 for electrically connecting the third connection pad 210 to the fourth connection pad 240. In this specification, the substrate wire 230 is indicated by a solid line to schematically show the electrical connection.

The semiconductor package 100 may include one or more semiconductor chips. Alternatively, the semiconductor package 100 may include a single semiconductor chip. The semiconductor chip may include a logic chip and a memory chip. The logic chip may include a central processing unit (CPU) chip, a graphics processing unit (GPU) chip, or an application processor (AP) chip. The memory chip may include a dynamic random-access memory (DRAM) chip, a static random-access memory (SRAM) chip, a flash memory chip, an electrically erasable and programmable read-only memory (EPROM) chip, a phase-change random-access memory (PRAM) chip, a magnetic random-access memory (MRAM) chip, or a resistive random-access memory (RRAM) chip.

The substrate 200 may include, for example, a printed circuit board (PCB) or a redistribution structure. When the substrate 200 includes a PCB, the substrate 200 may include a base layer, and the base layer may include a plurality of stacked sub-base layers. The upper and lower surfaces of the base layer may be covered by a solder resist layer. The third connection pad 210 and the fourth connection pad 240 may not be covered by the solder resist layer, and the third connection pad 210 and the fourth connection pad 240 may be exposed at the upper surface and the lower surface of the substrate 200, respectively.

In some embodiments, the base layer may include at least one material selected from a group consisting of phenolic resin, epoxy resin, and polyimide. For example, the base layer may include at least one material selected from a group consisting of flame retardant 4 (FR-4), tetrafunctional epoxy, polyphenylene ether, epoxy/polyphenylene oxide, bismaleimide triazine (BT), thermount, cyanate ester, polyimide, and liquid crystal polymer.

When the substrate 200 includes a redistribution structure, the substrate 200 may include a plurality of redistribution insulating layers and a redistribution pattern provided inside the redistribution insulating layers. The redistribution pattern may include a plurality of redistribution line patterns and a plurality of redistribution via patterns. The plurality of redistribution line patterns may be arranged between the plurality of redistribution insulating layers, and the plurality of redistribution via patterns may pass through the redistribution insulating layers to establish connections between the plurality of redistribution line patterns.

In some embodiments, the redistribution insulating layer may include an insulating material such as, for example, photo-imageable dielectric (PID) resin. In this case, the redistribution insulating layer may further include inorganic fillers. The redistribution pattern may include a conductive material such as, for example, copper (Cu), aluminum (Al), silver (Ag), tin (Sn), gold (Au), nickel (Ni), lead (Pb), and titanium (Ti), or an alloy thereof.

The substrate 200 may include an interposer. For example, the interposer may include a silicon interposer, an organic interposer, and a glass interposer including a glass core. The silicon interposer may include a plurality of through-silicon vias (TSVs) that at least partially pass through a silicon substrate.

Referring to FIG. 1B, the first connection pad 112 may include a first pad metal layer 112A and a first pad metal film 112B. The first pad metal film 112B may be provided on the first pad metal layer 112A. For example, one surface of the first pad metal layer 112A may be substantially uniformly covered by the first pad metal film 112B. The first pad metal layer 112A may have a shape in which the central region thereof partially protrudes toward the semiconductor package 100. The first pad metal layer 112A may be at least partially electrically connected to the second connection pad 111. For example, at least a portion of the first pad metal layer 112A may be in direct contact with a portion of the second connection pad 111. The second connection pad 111 may be electrically connected to a wiring structure included in the semiconductor package 100. The insulating layer 113 may be located between the second connection pad 111 and the first connection pad 112.

The first pad metal layer 112A may include copper (Cu), aluminum (Al), silver (Ag), nickel (Ni), lead (Pb), or titanium (Ti), including an alloy thereof. The first pad metal film 112B may include gold (Au), nickel (Ni), palladium (Pd), silver (Ag), or an alloy thereof. The first pad metal film 112B may include one or more metal films. The first pad metal film 112B may be in direct contact with the first connection terminal 120A.

The third connection pad 210 may include a third pad metal layer 210A and a third pad metal film 210B. The third pad metal film 210B may be provided on the third pad metal layer 210A. For example, one surface of the third pad metal layer 210A may be substantially uniformly covered by the third pad metal film 210B. The third pad metal film 210B may be in direct contact with the first connection terminal 120A.

The first connection terminal 120A may include a first terminal region 120A1 and a second terminal region 120A2. The first terminal region 120A1 may approximately have a spherical shape inside the first connection terminal 120A. The second terminal region 120A2 may cover a side surface of the first terminal region 120A1 that is exposed to the air. Therefore, the second terminal region 120A2 may not be located between the first terminal region 120A1 and the first connection pad 112.

The first terminal region 120A1 may include a metal material. The first terminal region 120A1 may include, for example, at least one from among tin (Sn), silver (Ag), copper (Cu), palladium (Pd), nickel (Ni), lead (Pb), bismuth (Bi), indium (In), and tantalum (Ta), including an alloy thereof.

The second terminal region 120A2 may include metal oxide formed due to oxidation of a material that forms the first connection terminal 120A. For example, the metal oxide in the second terminal region 120A2 may include, for example, tin oxide (SnO₂, SnO).

When the second terminal region 120A2 is formed, at a certain level or higher, on the first connection terminal 120A provided on one surface of the semiconductor package 100, the first connection terminal 120A may be non-wetting and thus not integrated with the connection material layer 220A. A non-wetting state may be due to the oxide layer formed on the surface of the first connection terminal 120A. The first connection terminal 120A may include a variety of metals and may also include tin (Sn). The oxide layer may be formed by the reaction with oxygen in the air. In this specification, the oxide layer on the solder ball may be referred to as the second terminal region 120A2.

As shown in FIG. 1B, the second terminal region 120A2 may be located between the first terminal region 120A1 of the first connection terminal 120A and the connection material layer 220A. As described above, the second terminal region 120A2 may include metal oxide. The second terminal region 120A2 having a certain thickness or more is located between the first terminal region 120A1 and the connection material layer 220A, and wetting between the first connection terminal 120A and the connection material layer 220A may not occur. Also, electric resistance may exceed a reference value, or electrical connection may not be established, resulting in a failure in an electrical connection between the semiconductor package 100 and the substrate 200. The connection material layer 220A may include solder paste. The connection material layer 220A may include, for example, at least one from among tin (Sn), silver (Ag), copper (Cu), palladium (Pd), nickel (Ni), lead (Pb), bismuth (Bi), indium (In), and tantalum (Ta), including an alloy thereof.

The second terminal region 120A2 may substantially uniformly surround the surface of the first terminal region 120A1. A portion of the surface of the first terminal region 120A1 may be in contact with the first connection pad 112, and the remainder of the surface of the first terminal region 120A1 may be surrounded by the second terminal region 120A2.

In the second terminal region 120A2, a first upper thickness TU1 at a first point, a first middle thickness TM1 at a second point, and a first lower thickness TD1 at a third point may be substantially similar to each other. The distance from the semiconductor package 100 may gradually increase in the order of the first point, the second point, and the third point. For example, the second point may be a point corresponding to half the height between the first connection pad 112 and the third connection pad 210, the first point may be a point corresponding to the middle between the second point and the first connection pad 112, and the third point may be a point corresponding to the middle between the second point and the third connection pad 210. The specific locations of the first point, the second point, and the third point are only examples, and embodiments are not limited thereto.

For example, the first upper thickness TU1 of the second terminal region 120A2 at the first point, the first middle thickness TM1 of the second terminal region 120A2 at the second point, and the first lower thickness TD1 of the second terminal region 120A2 at the third point may each be greater than or equal to 90 Å. Also, for example, in the second terminal region 120A2, the first upper thickness TU1 at the first point, the first middle thickness TM1 at the second point, and the first lower thickness TD1 at the third point may each be greater than or equal to 70 Å. Also, for example, in the second terminal region 120A2, the first upper thickness TU1 at the first point, the first middle thickness TM1 at the second point, and the first lower thickness TD1 at the third point may each be in a range of about 90 Å to about 200 Å. Also, for example, in the second terminal region 120A2, the first upper thickness TU1 at the first point, the first middle thickness TM1 at the second point, and the first lower thickness TD1 at the third point may each be in a range of about 70 Å to about 200 Å.

The thickness of the second terminal region 120A2 may be substantially understood as the distance from the corresponding point on the surface of the second terminal region 120A2 to a point on the surface of the first terminal region 120A1 closest thereto. For example, when the second terminal region 120A2 has a curved surface, the thickness of the second terminal region 120A2 at a certain point on the surface thereof may correspond approximately to the distance between the surface of the second terminal region 120A2 and the surface of the first terminal region 120A1 in the direction of the radius of curvature at the certain point stated above. For example, in a case in which the first terminal region 120A1 approximately has a spherical shape as shown in FIG. 1B, when a first center C1 approximately corresponds to the center of the first terminal region 120A1, the first lower thickness TD1 of the second terminal region 120A2 at the third point may represent the distance between the surface of the second terminal region 120A2 and the surface of the first terminal region 120A1 in a direction from the third point toward the first center C1. The description of the direction of the radius of curvature is provided for better understanding, and the thickness of the second terminal region 120A2 described by using the radius of curvature as an example does not limit the present disclosure. It should also be understood that the description of the thickness of the second terminal region 120A2 may equally apply to second terminal regions 120B2 and 120C2, which are described below.

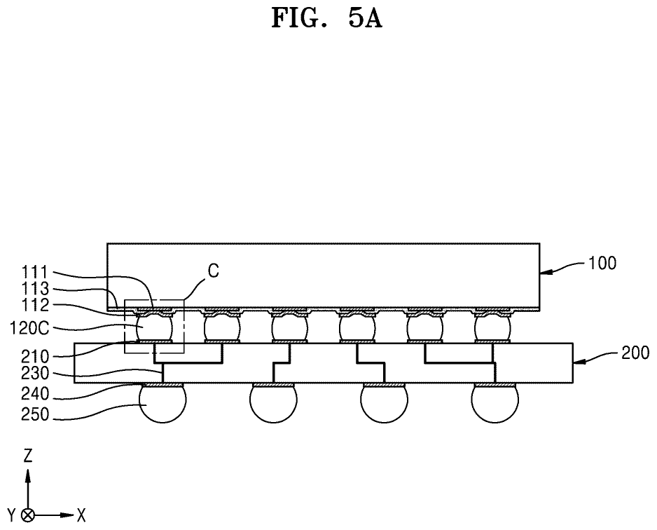

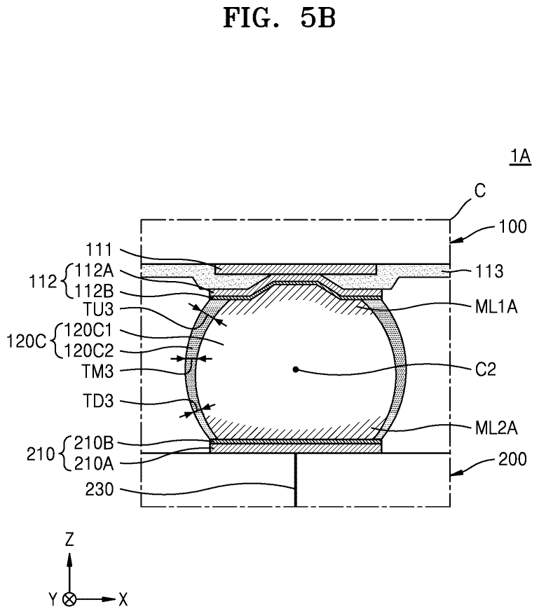

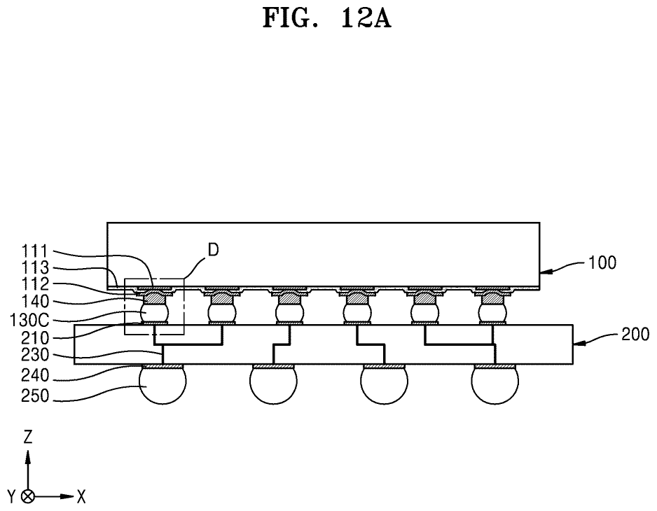

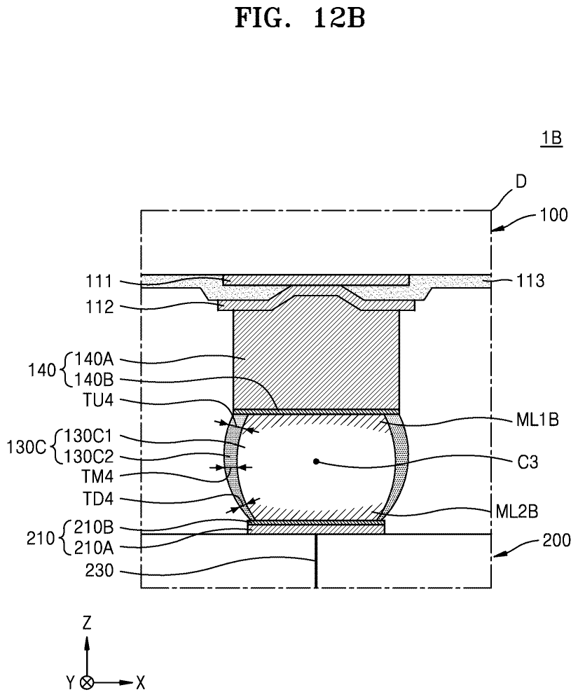

A second center C2 shown in FIG. 5B may approximately represent the center of a first terminal region 120C1, and a third center C3 shown in FIG. 12B may approximately represent the center of a first terminal region 130C1. The second center C2 and the third center C3 may be used as references for calculating the thicknesses of second terminal regions 120C2 and 130C2, respectively, like the first center C1 described above, but embodiments of the present disclosure are not limited thereto.

The first terminal region 120A1 may include a first terminal metal layer ML1A. The first terminal metal layer ML1A may be adjacent to the first connection pad 112. The first terminal metal layer ML1A may be part of the first terminal region 120A1. The first terminal metal layer ML1A may be partially in contact with the second terminal region 120A2. During a process of attaching the first connection terminal 120A to the first connection pad 112, a metal film contained in the first connection pad 112 may be integrated with the first connection terminal 120A thereby forming the first terminal metal layer ML1A. For example, the first terminal metal layer ML1A may include at least one from among a nickel-tin (Ni—Sn) alloy, a copper-tin (Cu—Sn) alloy, a gold-tin (Au—Sn) alloy, and a palladium-tin (Pd—Sn) alloy. The first terminal metal layer ML1A and a second terminal metal layer ML2A described below may include, for example, an intermetallic compound (IMC).

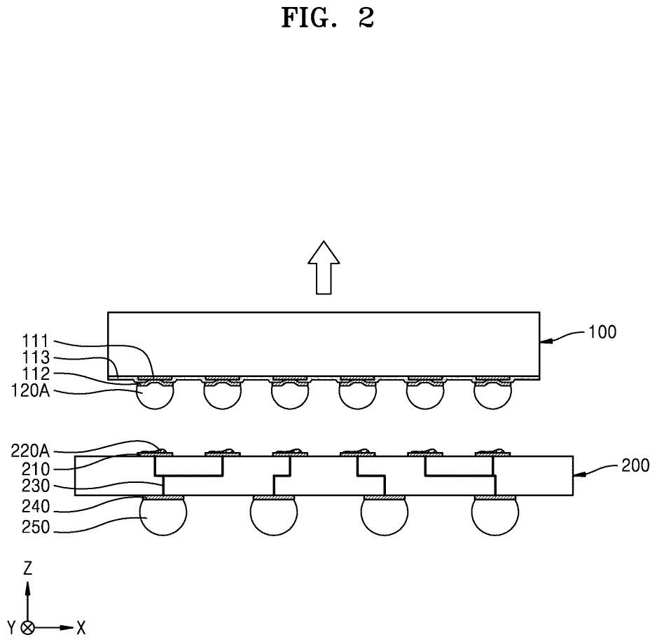

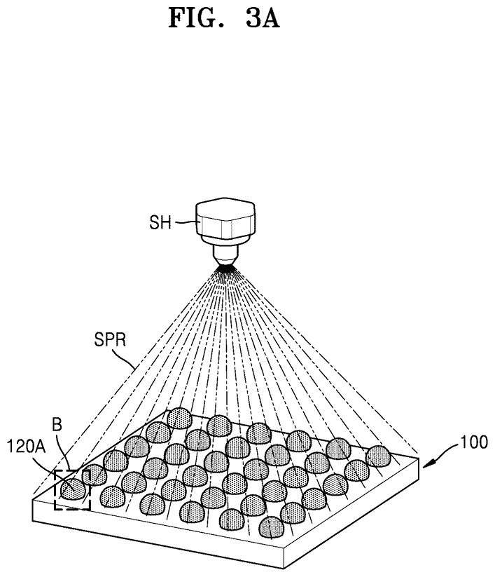

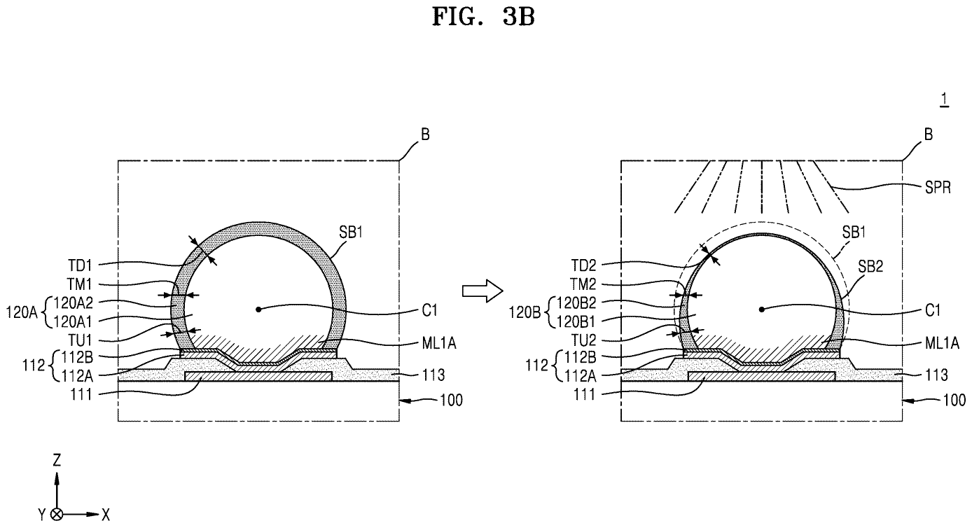

FIG. 2 is a cross-sectional view showing that the semiconductor package 100 of FIGS. 1A and 1B is separated from the substrate 200. FIG. 3A is a schematic perspective view showing that the first connection terminal 120A of the semiconductor package 100 separated from the substrate 200 is etched. FIG. 3B is an enlarged cross-sectional view of a region B of FIG. 3A, showing a change in the connection terminal during an etching process. More specifically, FIG. 3B is a cross-sectional view showing that the first connection terminal 120A is converted to a second connection terminal 120B by etching the second terminal region 120A2 of the first connection terminal 120A.

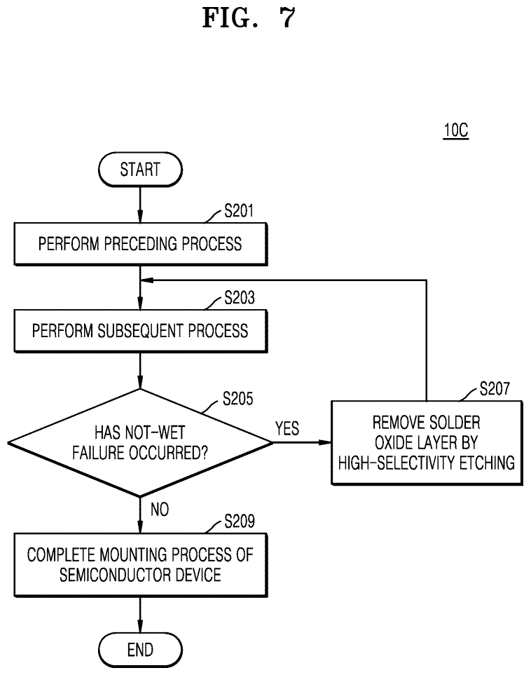

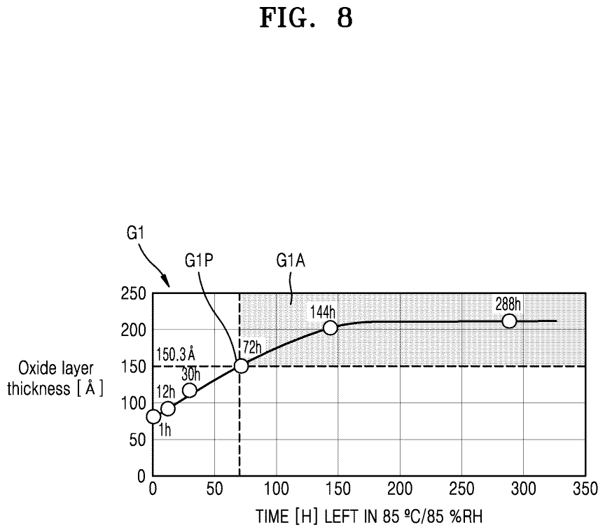

Referring to FIG. 2, when a poor electrical connection of the semiconductor package 100 is detected as described below with reference to FIGS. 7 and 8, the semiconductor package 100 may be removed from the substrate 200. For example, the semiconductor package 100 may be reheated and separated from the substrate 200. Also, for example, since the semiconductor package 100 is not normally bonded to the substrate 200 by the first connection terminal 120A, the semiconductor package 100 may be separated from the substrate 200 by a slight external force. FIG. 2 may correspond to a case in which the first connection terminal 120A is in a non-wetting state, as described with reference to FIGS. 1A and 1B.

As described with reference to FIGS. 1A and 1B, when separating the semiconductor package 100 from the substrate 200, the semiconductor package 100 may be more smoothly separated from the substrate 200 when the semiconductor package 100 is mounted on the substrate 200 by the first connection terminal 120A and the connection material layer 220A in a non-wetting state, compared to when the semiconductor package 100 is mounted on the substrate 200 by the connection terminal attached to the pad in a wetting state.

Referring to FIGS. 3A and 3B, the first connection terminal 120A of the semiconductor package 100 may be etched by an etching solution SPR. For example, the etching solution SPR sprayed from a spray nozzle SH may etch a plurality of first connection terminals 120A provided on the semiconductor package 100. The second terminal region 120A2 of the first connection terminal 120A may be etched.

The etching solution SPR may be sprayed onto one surface of the semiconductor package 100 to selectively etch some of components on the one surface of the semiconductor package 100. For example, the etching solution SPR may not etch the insulating layer 113 of the semiconductor package 100, but may etch the second terminal region 120A2 of the first connection terminal 120A. Also, the amount of the second terminal region 120A2 of the first connection terminal 120A being removed by the etching solution SPR may be relatively greater than the amount of components other than the first connection terminal 120A being removed.

The etching solution SPR may include a buffered oxide etch (BOE). The etching solution SPR may include an aqueous solution containing NH₄F and HF in a certain ratio. The etching solution SPR may include, for example, an aqueous solution containing NH₄F and HF in a ratio of about 10:1 to about 3:1. More specifically, the etching solution SPR may include, for example, NH₄F and HF in a ratio of 7:1.

As shown in FIG. 3B, the etching solution SPR may be sprayed to partially remove the second terminal region 120A2 of the first connection terminal 120A, thereby forming the second connection terminal 120B. A second surface SB2, which is a surface of the second connection terminal 120B, may have a shape due to the first connection terminal 120A being partially removed, compared to a first surface SB1, which is a surface of the first connection terminal 120A.

The etching solution SPR may be sprayed downward onto the semiconductor package 100. The second terminal regions 120A2 of the plurality of first connection terminals 120A provided on the semiconductor package 100 may be etched and partially removed. With respect to the first connection terminal 120A, an upper portion of the first connection terminal 120A, which is most directly exposed to the etching solution SPR, may be removed in the greatest amount in comparison to other portions of the second terminal region 120A2. Unlike the above, with respect to the first connection terminal 120A, a portion of the first connection terminal 120A, which is adjacent to the first connection pad 112 and not directly exposed to the etching solution SPR, may exhibit a relatively small amount of removal.

Non-uniform etching may occur at the first connection terminal 120A due to the etching solution SPR. Accordingly, a second terminal region 120B2 of the second connection terminal 120B formed by etching the first connection terminal 120A with the etching solution SPR may vary in thickness depending on locations. For example, the second terminal region 120B2 may increase in thickness toward the semiconductor package 100 or the first connection pad 112.

For example, the thickness of the upper portion of the second terminal region 120B2, which is away from the semiconductor package 100, may be less than the thickness of the lower portion of the second terminal region 120B2, which is towards the semiconductor package 100.

For example, the thickness of the second terminal region 120B2 may gradually increase in the order of a second lower thickness TD2 of the second terminal region 120B2 at a third point, a second middle thickness TM2 thereof at a second point, and a second upper thickness TU2 thereof at a first point. The distance from the semiconductor package 100 may gradually increase in the order of the first point, the second point, and the third point.

For example, in the second terminal region 120B2, the second upper thickness TU2 at the first point may be in a range of about 90 Å to about 190 Å. In the second terminal region 120B2, the second middle thickness TM2 at the second point may be in a range of about 50 Å to about 120 Å. In the second terminal region 120B2, the second lower thickness TD2 at the third point may be in a range of about 5 Å to about 70 Å. Also, a portion of the second terminal region 120B2, which is farthest away from the semiconductor package 100, and the vicinity thereof, may be completely removed.

The thickness of the thickest portion of the second terminal region 120B2 may be about 3 times to about 10 times the thickness of the thinnest portion of the second terminal region 120B2. Also, the thickness of the thickest portion of the second terminal region 120B2 may be about 5 times to about 30 times the thickness of the thinnest portion of the second terminal region 120B2.

The metal oxide contained in the second terminal region 120A2 may be removed by the etching solution SPR. For example, the metal oxide that may be contained in the second terminal region 120A2 may include tin oxide. A reaction in which the tin oxide is removed by the etching solution SPR may be as shown in a first chemical formula and a second chemical formula below.

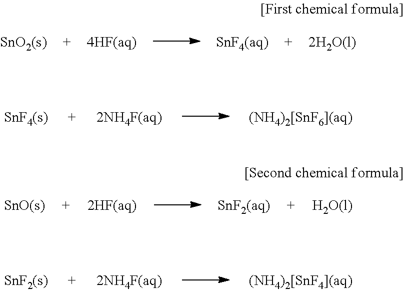

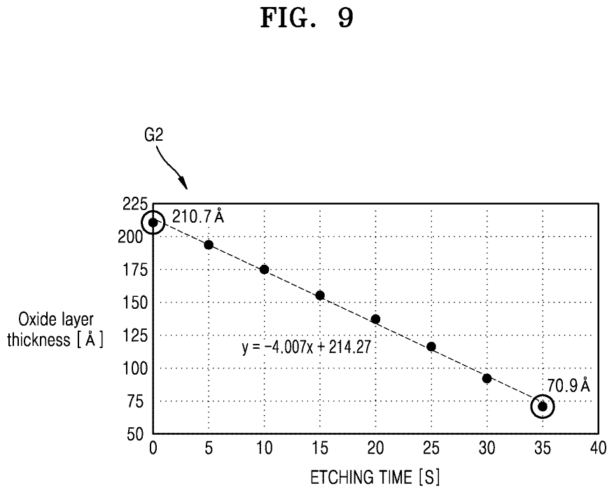

When the metal oxide contained in the second terminal region 120A2 is removed by the etching solution SPR, the amount of metal oxide to be removed may substantially increase as time during which the first connection terminal 120A is exposed to the etching solution SPR increases. Specific values for the above are described below in detail with reference to FIG. 9.

As the thickness of the second terminal region 120B2 of the second connection terminal 120B increases, the time required in an etching process for reprocessing solder balls increases. For example, the thickness of the second terminal region 120A2 in the upper portion of the first connection terminal 120A, which is a region to be connected to a connection pad in a mounting process of the semiconductor package 100, may be 100 Å. The thickness of the oxide layer for a normal wetting state between a connection terminal and a connection pad may be set to, for example, 50 Å. That is, it can be seen that, since approximately 50 Å of the thickness of the second terminal region 120A2 in the upper portion of the first connection terminal 120A needs to be removed by etching, the first connection terminal 120A has to be exposed to the etching solution SPR for at least 15 seconds, as shown in FIG. 9. That is, the time during which the first connection terminal 120A is exposed to the etching solution SPR may be adjusted according to the thickness of an oxide layer that is the second terminal region 120A2, thereby etching and removing the oxide layer at an appropriate level.

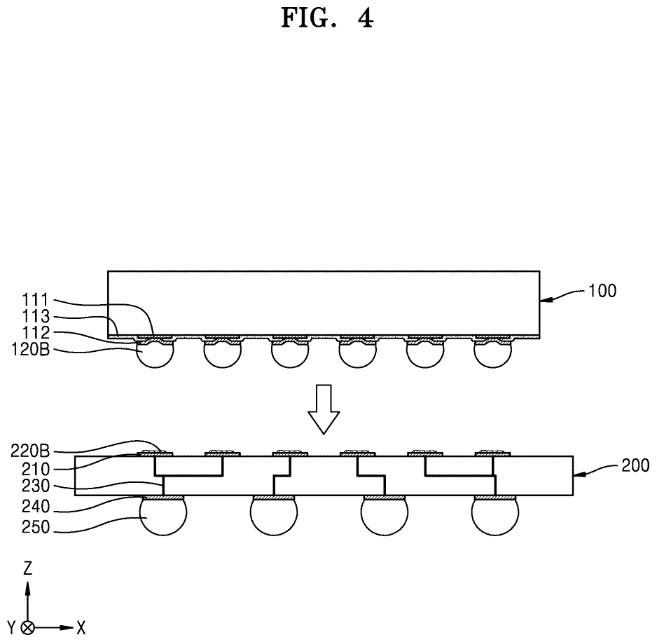

FIG. 4 is a cross-sectional view showing that the semiconductor package 100 that has undergone the etching process of FIGS. 3A and 3B is mounted on the substrate 200.

Referring to FIG. 4, a process of mounting, on the substrate 200, the semiconductor package 100 that has undergone the etching process may be performed. The semiconductor package 100 may be mounted on the substrate 200 by, for example, a heat-pressing method to a connection material layer 220B that is disposed previously on the third connection pad 210 provided on the substrate 200. As described below with reference to FIGS. 5A and 5B, when the mounting process is performed by bringing the second connection terminal 120B in contact with the connection material layer 220B after sufficiently removing the oxide layer, the second connection terminal 120B and the connection material layer 220B may be integrated with each other to form a third connection terminal 120C. The third connection terminal 120C is described below in detail with reference to FIGS. 5A and 5B.

FIG. 5A is a cross-sectional view of the semiconductor package 100 according to embodiments. FIG. 5B is an enlarged cross-sectional view showing region C in the semiconductor package 100 of FIG. 5A. Those components not described below may be substantially the same as the above.

Referring to FIGS. 5A and 5B, a portion of the third connection terminal 120C may be in contact with the first connection pad 112, and another portion of the third connection terminal 120C may be in contact with the third connection pad 210. The thickness of the second terminal region 120B2 of the second connection terminal 120B may generally decrease with increasing distance from the semiconductor package 100, and thus, the thickness of a second terminal region 120C2 of the third connection terminal 120C formed by integrating the second connection terminal 120B with the connection material layer 220B may generally decrease with increasing distance from the semiconductor package 100.

The second terminal region 120C2 of the third connection terminal 120C may vary in thickness depending on locations. For example, the second terminal region 120C2 may increase in thickness toward the semiconductor package 100 or the first connection pad 112.

For example, the thickness of a portion of the second terminal region 120C2, which is adjacent to the third connection pad 210, may be less than the thickness of a portion of the second terminal region 120C2, which is adjacent to the first connection pad 112.

For example, the thickness of the second terminal region 120C2 may gradually increase in the order of a third lower thickness TD3 of the second terminal region 120C2 at a third point, a third middle thickness TM3 thereof at a second point, and a third upper thickness TU3 thereof at a first point. The distance from the semiconductor package 100 may gradually increase in the order of the first point, the second point, and the third point.

For example, in the second terminal region 120C2, the third upper thickness TU3 at the first point may be in a range of about 90 Å to about 190 Å. In the second terminal region 120C2, the third middle thickness TM3 at the second point may be in a range of about 50 Å to about 120 Å. In the second terminal region 120C2, the third lower thickness TD3 at the third point may be in a range of about 5 Å to about 70 Å.

The thickness of the thickest portion of the second terminal region 120C2 may be about 3 times to about 10 times the thickness of the thinnest portion of the second terminal region 120C2. Also, the thickness of the thickest portion of the second terminal region 120C2 may be about 5 times to about 30 times the thickness of the thinnest portion of the second terminal region 120C2.

A first terminal region 120C1 of the third connection terminal 120C may include the first terminal metal layer ML1A. The first terminal metal layer ML1A may be adjacent to the first connection pad 112. Also, the first terminal metal layer ML1A may be in contact with the first connection pad 112. The first terminal metal layer ML1A may be part of the first terminal region 120C1. The first terminal metal layer ML1A may be partially in contact with the second terminal region 120C2.

The first terminal region 120C1 may include the second terminal metal layer ML2A. The second terminal metal layer ML2A may be adjacent to the third connection pad 210. Also, the second terminal metal layer ML2A may be in contact with the third connection pad 210. The second terminal metal layer ML2A may be part of the first terminal region 120C1. The second terminal metal layer ML2A may be partially in contact with the second terminal region 120C2. During a process of attaching the second connection terminal 120B to the third connection pad 210, a metal film contained in the third connection pad 210 may be integrated with the second connection terminal 120B, thereby forming the second terminal metal layer ML2A. For example, the second terminal metal layer ML2A may include at least one from among a nickel-tin (Ni—Sn) alloy, a copper-tin (Cu—Sn) alloy, a gold-tin (Au—Sn) alloy, and a palladium-tin (Pd—Sn) alloy. The second terminal metal layer ML2A may include, for example, an IMC.

According to embodiments, in a semiconductor package 1 including the second connection terminal 120B shown on the right side of FIG. 3B and in a semiconductor package 1A including the third connection terminal 120C shown in FIG. 5B, the mounting process of the semiconductor package 100 may be performed by selectively and non-uniformly removing the metal oxide layer of the connection terminal of the semiconductor package 100 by the etching process. Accordingly, the solder ball, which is the connection terminal, may wet the connection pad to facilitate the electrical connection by the connection terminal. Therefore, in the semiconductor packages 1 and 1A according to embodiments, the oxide layer of the connection terminal provided in the semiconductor package may be selectively etched to prevent or eliminate the electrical connection failure caused by the oxide layer of the solder ball in the semiconductor package. In addition, semiconductor packages having non-wetting failures may be reprocessed and used.

In the semiconductor packages 1 and 1A according to embodiments and a semiconductor package 1B described below, the semiconductor package 100 is mounted on the substrate 200 as an example, but embodiments of the present disclosure may also include a case in which the semiconductor package 100 is mounted on a connection pad provided on another semiconductor device.

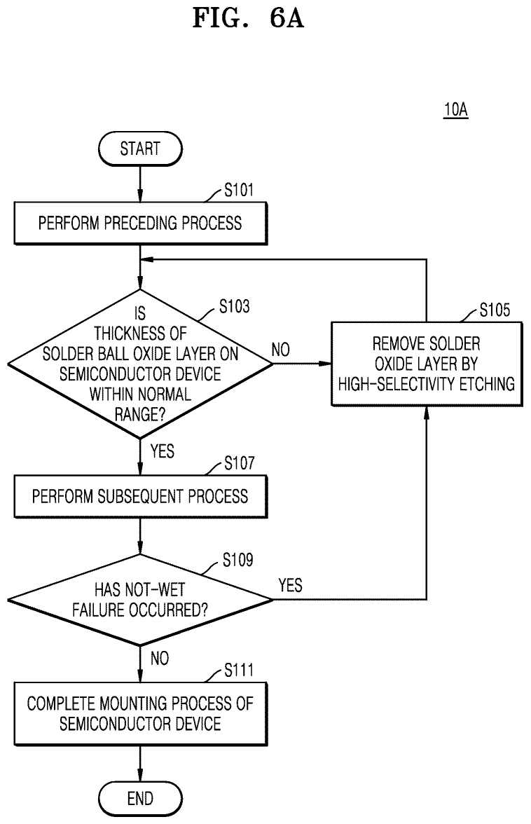

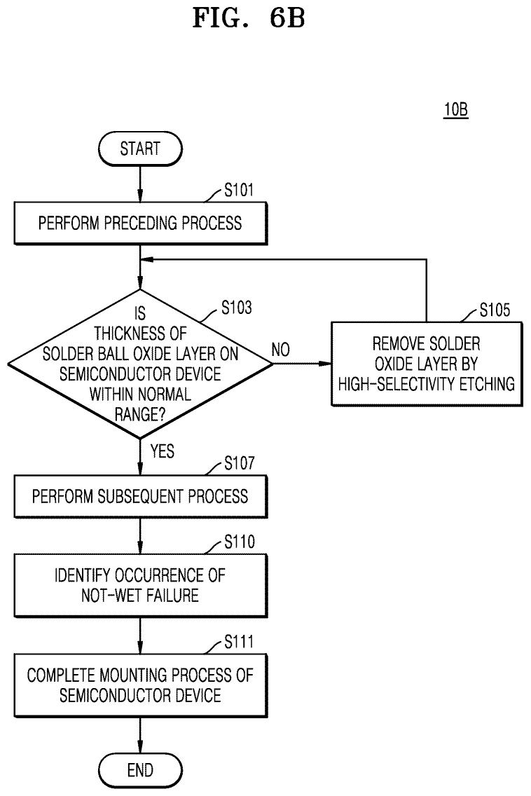

FIG. 6A is a flowchart showing a semiconductor package reprocessing method 10A according to embodiments. FIG. 6B is a flowchart showing a semiconductor package reprocessing method 10B according to embodiments. FIG. 7 is a flowchart showing a semiconductor package reprocessing method 10C according to embodiments.

Referring to FIG. 6A, a preceding process of manufacturing a semiconductor package may be performed (operation S101). For example, the preceding process may include a process of manufacturing the semiconductor package, such as forming a redistribution layer, mounting a semiconductor chip on the redistribution layer, and performing a molding process, to manufacture the semiconductor package.

The preceding process may include a process of placing a connection terminal on the semiconductor package. For example, the preceding process may include a process of forming a metal layer on the connection pad formed on the semiconductor package and a cleaning process of removing contaminants on the surface of the pad. Connection terminals may be respectively arranged on a plurality of connection pads. For example, the preceding process may include placing solder balls by using ball stamping or placing solder balls by using jetting equipment. Subsequently, the solder balls may be melted on the connection pads by a reflow soldering process and then solidified, and thus, the solder balls may be coupled to the connection pads.

The semiconductor package reprocessing method 10A may include an operation S103 of identifying whether a thickness of an oxide layer (hereinafter, referred to as an oxide layer thickness) of the connection terminal is within a normal range after the connection terminal is disposed on the semiconductor package. For example, as described with reference to FIG. 8 below, when the solder ball is exposed to an environment with high-temperature and/or high-humidity for a certain period of time, the thickness of the oxide layer may increase. For example, when exposed for about 1 hour, the oxide layer thickness may be about 80.9 Å.

The normal range of the oxide layer thickness may be set to less than or equal to a first reference thickness. For example, the first reference thickness may be in a range of about 50 Å to about 90 Å. The normal range of the oxide layer thickness may be set to be less than the first reference thickness. For example, the first reference thickness may be set to 70 Å. Accordingly, the normal range of the oxide layer thickness may be set to 70 Å or less according to the first reference thickness.

Depending on the first reference thickness of the oxide layer, a first reference time during which the semiconductor package having the solder ball has been left may be set. For example, when the oxide layer thickness increases over the first reference time in a high-temperature, high-humidity environment, the oxide layer with the first reference thickness of 70 Å or more may be observed. Here, when the semiconductor package with the solder ball is left for a period of the first reference time, and operation S105 of removing a solder oxide layer by high-selectivity etching may be performed.

Also, the degree of formation of the oxide layer on the solder balls formed on the semiconductor device may be determined by, for example, inspecting with an optical inspection apparatus, such as a vision optical microscope and an electron microscope, the semiconductor package in which the solder balls have been formed. To identify that the oxide layer of the solder ball is relatively thick, an operation S103 of identifying whether the oxide layer thickness of the connection terminal is within the normal range is performed after the connection terminal is disposed on the semiconductor package. When it is determined that the oxide layer thickness is out of the normal range, the operation S105 of removing the solder oxide layer by the high-selectivity etching may be performed.

Then, a subsequent process may be performed (operation S107). The subsequent process may include a process of mounting the semiconductor package on a substrate. For example, the subsequent process may include screen printing, mounting of the semiconductor package, and a reflow process.

After the subsequent process is performed (the operation S107), an operation S109 of determining whether a non-wetting failure has occurred may be performed. The method of identifying whether the non-wetting failure has occurred may include, for example, identifying whether the solder ball is in a wetting state by using an optical microscope or magnifying glass, inspecting whether the solder ball wets a pad by using a high-resolution camera and image processing, performing non-destructive inspection by using X-ray, performing a test by using levels of electrical signal conduction, and applying a small external force.

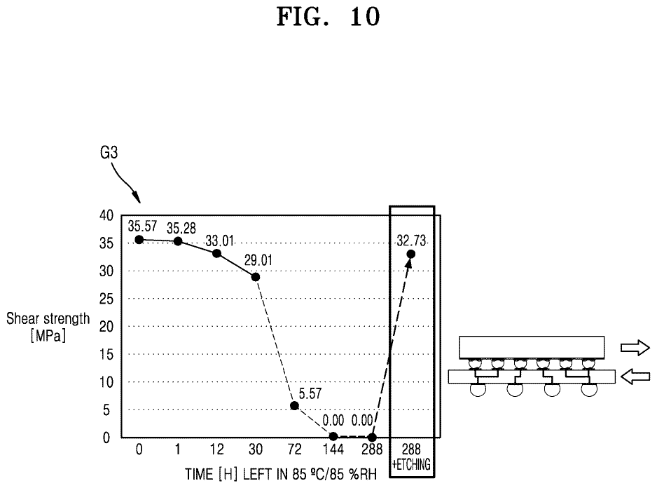

For example, when the semiconductor package is left in the high-temperature, high-humidity environment for a long period of time, non-wetting failures may occur more frequently due to the oxide layer formed on the solder balls, as shown in a third graph G3 in FIG. 10 which is described below, resulting in weakening of adhesion strength between the semiconductor package and the substrate. For example, when shear stress is applied between the semiconductor package and the substrate, bonding regions between the semiconductor package and the substrate may be separated at a lower level of shear stress than when the solder ball is normally bonded.

For example, when the semiconductor package with the solder balls has been left for 72 hours, the solder balls are separated when shear stress of 5.57 MPa is applied. Also, for example, when the semiconductor package with the solder balls has been left for about 144 hours to about 288 hours, the solder balls may be separated even when little shear stress is applied thereto, that is, the solder balls may not adhere to the connection pad at all. Therefore, the non-wetting failure of the solder ball may be identified with a relatively lower level of shear force.

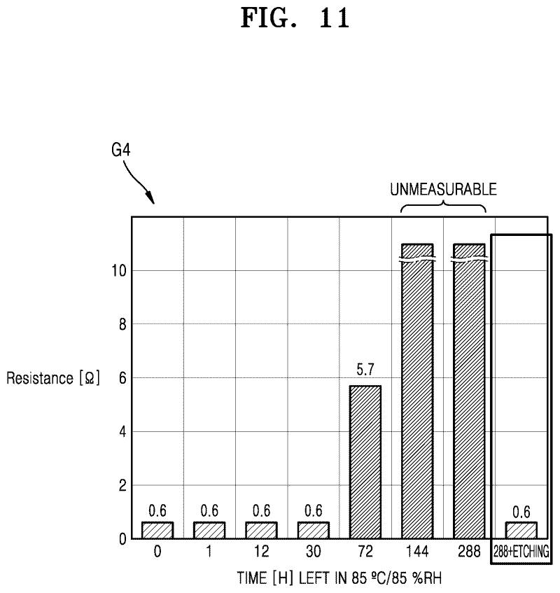

For example, as shown in a fourth graph G4 of FIG. 11, which is described below, when the semiconductor package with the solder balls has been left for a long period of time in a high-temperature, high-humidity environment, the value of resistance detected in the solder balls increases. For example, when the time for which the semiconductor package has been left is 72 hours, exceeding 30 hours, the resistance value of the solder balls may be measured up to 5.7Ω, which significantly increases compared to the resistance value of 0.6Ω in a case in which the semiconductor package has been left for about 0 to about 30 hours. In the case of 144 hours and 288 hours, the resistance value is not measured, that is, the result shows that there is no electrical connection between the solder ball and the pad. Therefore, the electrical test may be used to identify whether the non-wetting failure of the solder ball has occurred.

When it is identified that the non-wetting failure has occurred in the operation S109 of identifying whether the non-wetting failure of the solder ball has occurred, the operation S105 of removing the solder oxide layer by high-selectivity etching may be performed. When it is identified that no non-wetting failure has occurred in the operation S109 of identifying whether the non-wetting failure has occurred in the solder ball, an operation S111 of completing a mounting process of the semiconductor package may be performed, and a series of operations of the semiconductor package reprocessing method 10A may be terminated.

The operation S105 of removing the oxide layer of the solder ball by the high-selectivity etching may include the etching process performed in FIGS. 3A and 3B. The high-selectivity etching indicates that the degree of etching the oxide layer of the solder ball has a large difference from the degree of etching the other components. Also, in the operation of removing the oxide layer of the solder ball, the oxide layer of the solder ball is not removed uniformly as described above, but rather, a region of the oxide layer of the solder ball, which is relatively more exposed to the etching solution SPR, may be etched more significantly. Therefore, the selective and non-uniform etching may be performed on the oxide layer of the solder ball.

After the operation S105 of removing the oxide layer of the solder ball, at least some of the operations described above may be performed again to complete the mounting process of the semiconductor device (the operation S111).

Referring to FIG. 6B, the semiconductor package reprocessing method 10B may include the operation S101 of performing a preceding process. The preceding process may include, for example, the process of manufacturing the semiconductor chip. The process of manufacturing the semiconductor chip may include forming various types of oxide layers, metal layers, insulating layers, device layers, and wire layers.

After the preceding process is performed (the operation S101), the operation S103 of identifying whether the oxide layer thickness of the connection terminal is within the normal range may be performed. The operation S103 of identifying whether the oxide layer thickness is within the normal range may be substantially the same as that described with reference to FIG. 6A.

In the operation S103 of identifying whether the oxide layer thickness is within the normal range, when it is identified that the oxide layer thickness is not within the normal range, the operation S105 of removing the solder oxide layer by the high-selectivity etching may be performed. In the operation S103 of identifying whether the oxide layer thickness is within the normal range, when it is identified that the oxide layer thickness is within the normal range, the operation S107 of performing the subsequent process may be performed.

In the operation S107 of performing a subsequent process, the subsequent process may include, for example, a wafer level package (WLP) process. That is, the subsequent process may include back-grinding the semiconductor chip, dicing the semiconductor chip, mounting the semiconductor chip by a flip-chip method, molding the semiconductor chip, and individualizing a wafer on which the semiconductor chip is mounted.

For example, in the operation S110 of identifying whether a non-wetting failure has occurred, even if a non-wetting failure is detected, the operation S105 of removing the solder oxide layer by high-selectivity etching may be restricted for process reasons. For example, as described above, when performing the WLP process, the non-wetting failure may be detected through an electrical test after the semiconductor chip is disposed on the wafer. In this case, the operation S105 of removing the solder oxide layer by high-selectivity etching may be restricted for the semiconductor chip. However, in performing the WLP process, the operation S105 of removing the solder oxide layer by high-selectivity etching may be performed as described with reference to FIG. 6A.

The semiconductor package reprocessing method 10B includes the operation S103 of identifying whether the oxide layer thickness of the connection terminal of the semiconductor package is within the normal range before the operation S107 of performing the subsequent process. When the oxide layer thickness is not within the normal range, the non-wetting failure may be prevented by the operation S105 of removing the solder oxide layer by high-selectivity etching. Therefore, in the mounting of semiconductor devices by the semiconductor package reprocessing method 10B according to embodiments, the yield of the semiconductor package may be prevented from deteriorating due to the occurrence of non-wetting failures.

Referring to FIG. 7, a preceding process of manufacturing a semiconductor package may be performed (operation S201). The preceding process of FIG. 7 may include a process of forming a solder ball on a semiconductor package and a process of mounting the semiconductor package on a target.

After the preceding process is performed, a subsequent process may be performed (operation S203). After the subsequent process is performed (operation S203), an operation S205 of identifying whether a non-wetting failure has occurred may be performed. When it is identified that the non-wetting failure has occurred, an operation S207 of removing the solder oxide layer by high-selectivity etching may be performed. After the operation S207 of removing the oxide layer of the solder ball is performed, the subsequent process may be performed again (operation S203), and/or the operation S205 of determining whether a non-wetting failure has occurred may be performed. After the subsequent process is performed (S203) and the operation S205 of determining whether a non-wetting failure has occurred is performed, an operation S209 of completing the mounting process of the semiconductor device is performed. Accordingly, a series of operations of the semiconductor package reprocessing method 10C may be terminated.

Unlike FIG. 6A, FIG. 7 does not include the operation S103 of identifying whether the oxide layer thickness of the solder ball is within the normal range after the solder ball is formed in the semiconductor package. Instead, the operation S205 of determining whether a non-wetting failure has occurred is performed after the semiconductor package is mounted on the target in the subsequent process.

Through the semiconductor package reprocessing methods 10A, 10B, and 10C for the solder balls according to embodiments, the oxide layer of the solder balls in the semiconductor packages may be selectively and non-uniformly etched to prevent or eliminate electrical connection failures caused by the oxide layer of the solder balls in the semiconductor packages.

FIG. 8 shows the relationship between the thickness of the oxide layer and the time for which the oxide layer has been left in a high-temperature, high-humidity environment. FIG. 9 shows the relationship between the thickness of the oxide layer and the etching time. FIG. 10 is a graph showing, as shear strength, the relationship between the bonding strength of solder balls and the time for which the solder balls have been left in a high-temperature, high-humidity environment. FIG. 11 is a graph showing, as electric resistance, the relationship between the resistance of the solder ball and the connection pad and the time for which the solder ball has been left in a high-temperature, high-humidity environment. In the below description, descriptions of aspects that are substantially the same as aspects described above may not be repeated.

Referring to FIG. 8, a first graph G1 of FIG. 8 shows the relationship between the thickness of the oxide layer of the solder ball exposed to a high-temperature, high-humidity environment and the time for which the solder ball has been exposed to the high-temperature, high-humidity environment. The high-temperature, high-humidity environment illustrated in the first graph G1 is based on an environment of 85° C. and 85% relative humidity, and the thickness of the oxide layer on the solder ball is shown. For example, when the solder ball is exposed to the high-temperature, high-humidity environment for 72 hours, as shown by a first graph point GIP, an oxide layer having a thickness of approximately 150 Å may be formed on the solder ball. Generally, it can be seen that, within a range of less than 150 hours of exposure to the high-temperature, high-humidity environment, the thickness of the oxide layer increases as the exposure time increases. Through the first graph G1, the first reference thickness, which is the reference at which non-wetting failure of the oxide layer does not occur, and the first reference time, which is the time at which the oxide layer thickness reaches the first reference thickness in the high-temperature, high-humidity environment, may be set. When the solder ball has been formed and left on the semiconductor package for more than the first reference time, the oxide layer may have thickened to the point at which non-wetting failure occurs. Therefore, the oxide layer on the solder ball may be removed by the high-selectivity etching to prevent non-wetting failure.

For example, in a first region GIA of the first graph G1, a non-wetting failure of the solder ball may occur. Therefore, the first reference thickness may be set to 150 Å, and accordingly, the first reference time may be set to 72 hours. The examples of the first reference thickness and the first reference time are provided for better understanding. The first reference thickness and the first reference time may be set differently for various reasons, such as the material of the solder ball, the characteristics of the environment to which the solder ball is exposed, and the safety factor. Therefore, embodiments of the present disclosure are not limited by the examples of the first reference thickness and the first reference time.

Referring to FIG. 9, a second graph G2 shows the relationship between the time taken to etch the oxide layer of the solder ball, that is, the time for which the solder ball is exposed to the etching solution SPR described above, and the thickness of the oxide layer of the solder ball. For example, as shown in the second graph G2, when the thickness of the oxide layer on the solder ball is about 210 Å before etching, the thickness of the oxide layer removed from the solder ball generally decreases proportionally as the etching time increases. That is, it can be seen that the thickness of the oxide layer remaining on the solder ball decreases linearly as the etching time increases. For example, the thickness of the oxide layer on the solder ball exposed to the etching solution SPR for 35 seconds may be reduced from the initial 210 Å to about 70 Å.

Through the relationship between the etching time and the oxide layer removed from the solder ball, the etching time for which the solder ball is exposed to the etching solution may be adjusted according to the thickness of the oxide layer on the solder ball. In addition, through this relationship, the thickness of the oxide layer on the solder ball may be reduced by adjusting the etching time to minimize the possibility of occurrence of non-wetting failures of the solder ball.

Referring to FIG. 10, the third graph G3 shows the shear strength that separates the solder ball from a target when the solder ball is mounted on the target in the high-temperature, high-humidity environment. For example, when the solder ball has been left in the high-temperature, high-humidity environment for 30 hours, the bonding region of the solder ball is separated by the shear strength of about 29 MPa. However, when left in the high-temperature, high-humidity environment for 72 hours, the bonding region of the solder ball is separated by the shear strength of 5.57 MPa. In addition, when left for more than 144 hours, the bonding of the solder ball is not established, resulting in the failure to withstand the shear strength.

However, the process of removing the solder oxide layer by high-selectivity etching in the semiconductor package reprocessing methods 10A and 10B according to embodiments of the present disclosure may be performed on solder balls that have been left in the high-temperature, high-humidity environment for more than 288 hours. As a result, it can be seen that the solder ball is bonded properly, and thus, the shear strength that the solder ball may withstand is restored to normal levels.

Referring to FIG. 11, the fourth graph G4 shows the magnitude of the resistance between the target and the solder ball when the solder ball is exposed to the high-temperature, high-humidity environment and mounted on the target. When the solder ball has been left in the high-temperature, high-humidity environment for 30 hours or less, the resistance value of the solder ball is measured to be 0.6Ω. However, it can be seen that when the solder ball has been left for 72 hours, the resistance value is measured to be 5.7Ω, and when left for 144 hours or more, the resistance value may not be measured. When the solder balls are left in the high-temperature, high-humidity environment for 144 hours or more, the oxide layer on the solder ball becomes excessively thick, and the solder ball may not be bonded to the connection pad at all. As a result, the solder ball and the connection pad are not electrically connected to each other, which may result in measurement failure.

However, the process of removing the solder oxide layer by high-selectivity etching in the semiconductor package reprocessing methods 10A and 10B according to embodiments of the present disclosure may be performed on solder balls that have been left in the high-temperature, high-humidity environment for more than 288 hours. As a result, it can be seen that the solder ball is bonded properly, and thus, the magnitude of the resistance between the solder ball and the target connected thereto is completely restored to normal levels.

FIG. 12A is a cross-sectional view of a semiconductor package according to embodiments. FIG. 12B is an enlarged cross-sectional view showing region D in the semiconductor package of FIG. 12A. In the below description, descriptions of aspects that are substantially the same as aspects described above may not be repeated.

Referring to FIGS. 12A and 12B, a portion of a fourth connection terminal 130C may be in contact with one surface of a conductive pillar 140 provided on the first connection pad 112, and another portion of the fourth connection terminal 130C may be in contact with the third connection pad 210.

The conductive pillar 140 may be provided on the first connection pad 112 such that one end of the conductive pillar 140 is in contact with one surface of the first connection pad 112, and the other end of the conductive pillar 140 is in contact with the fourth connection terminal 130C. The conductive pillar 140 may include a first pillar 140A and a pillar metal film 140B provided on one surface of the first pillar 140A. For example, one surface of the first pillar 140A may be substantially uniformly covered by the pillar metal film 140B. The pillar metal film 140B may include gold (Au), nickel (Ni), palladium (Pd), silver (Ag), or an alloy thereof.

A second terminal region 130C2 of the fourth connection terminal 130C may vary in thickness depending on locations. The thickness of the second terminal region 130C2 of the fourth connection terminal 130C may generally decrease with increasing distance from the semiconductor package 100. For example, the second terminal region 130C2 may increase in thickness toward the semiconductor package 100 or the conductive pillar 140.

For example, the thickness of a portion of the second terminal region 130C2, which is adjacent to the third connection pad 210, may be less than the thickness of a portion of the second terminal region 130C2, which is adjacent to the conductive pillar 140.

For example, the thickness of the second terminal region 130C2 may gradually increase in the order of a fourth lower thickness TD4 of the second terminal region 130C2 at a third point, a fourth middle thickness TM4 thereof at a second point, and a fourth upper thickness TU4 thereof at a first point. The distance from the semiconductor package 100 may gradually increase in the order of the first point, the second point, and the third point.

For example, in the second terminal region 130C2, the fourth upper thickness TU4 at the first point may be in a range of about 90 Å to about 190 Å. In the second terminal region 130C2, the fourth middle thickness TM4 at the second point may be in a range of about 50 Å to about 120 Å. In the second terminal region 130C2, the fourth lower thickness TD4 at the third point may be in a range of about 5 Å to about 70 Å. The thickness of the thickest portion of the second terminal region 130C2 may be about 3 times to about 10 times the thickness of the thinnest portion of the second terminal region 130C2. Also, the thickness of the thickest portion of the second terminal region 130C2 may be about 5 times to about 30 times the thickness of the thinnest portion of the second terminal region 130C2.

The first terminal region 130C1 may include a first terminal metal layer ML1B and a second terminal metal layer ML2B. The first terminal metal layer ML1B may be adjacent to the conductive pillar 140. Also, the first terminal metal layer ML1B may be in contact with the conductive pillar 140. The first terminal metal layer ML1B may be part of the first terminal region 130C1. The first terminal metal layer ML1B may be partially in contact with the second terminal region 130C2.

The second terminal metal layer ML2B may be adjacent to the third connection pad 210. Also, the second terminal metal layer ML2B may be in contact with the third connection pad 210. The second terminal metal layer ML2B may be part of the first terminal region 130C1. The second terminal metal layer ML2B may be partially in contact with the second terminal region 130C2. The first terminal metal layer ML1B and the second terminal metal layer ML2B may each include at least one from among a nickel-tin (Ni—Sn) alloy, a copper-tin (Cu—Sn) alloy, a gold-tin (Au—Sn) alloy, and a palladium-tin (Pd—Sn) alloy.

In the semiconductor package 1B including the fourth connection terminal 130C shown in FIG. 12B, the etching process of selectively and non-uniformly removing the metal oxide layer of the connection terminal of the semiconductor package 100 is performed, and then the mounting process of the semiconductor package 100 is performed. Accordingly, the solder ball, which is the connection terminal, may wet the connection pad to facilitate the electrical connection by the connection terminal. Therefore, in the semiconductor package 1B according to embodiments, the oxide layer of the connection terminal provided in the semiconductor package may be selectively etched to prevent or eliminate the electrical connection failure caused by the oxide layer of the solder ball in the semiconductor package.

While non-limiting example embodiments of the present disclosure have been particularly described with reference to accompanying drawings, it will be understood that various changes in form and details may be made therein without departing from the spirit and scope of the present disclosure.

What is claimed is:

1. A semiconductor package comprising:
a semiconductor device;
a first connection pad on one surface of the semiconductor device;
a connection terminal at one end of the first connection pad; and
a second connection pad in contact with the connection terminal,
wherein the connection terminal is between the first connection pad and the second connection pad,
wherein the connection terminal comprises a first terminal region and a second terminal region,
wherein the first terminal region is at least partially surrounded by the second terminal region, and
wherein the second terminal region comprises an oxidized metal, and a thickness of the second terminal region varies.

2. The semiconductor package of claim 1, wherein a portion of the second terminal region adjacent to the first connection pad has a greater thickness than a thickness of a portion of the second terminal region adjacent to the second connection pad.

3. The semiconductor package of claim 1, wherein a portion of the second terminal region has a thickness less than or equal to 70 Å.

4. The semiconductor package of claim 1, wherein the thickness of the second terminal region decreases with increasing distance from the first connection pad.

5. The semiconductor package of claim 1, wherein a first section of the second terminal region has a thickness less than or equal to 90 Å,
wherein a second section of the second terminal region has a thickness greater than or equal to 120 Å, and
wherein the first section of the second terminal region is farther than the second section of the second terminal region from the first connection pad.

6. The semiconductor package of claim 1, wherein the thickness of the second terminal region at a first point of the second terminal region is greater than the thickness of the second terminal region at a second point of the second terminal region,
wherein the thickness of the second terminal region at the second point of the second terminal region is greater than the thickness of the second terminal region at a third point of the second terminal region,
wherein a distance from the first connection pad to the second point is farther than a distance from the first connection pad to the first point, and
wherein a distance from the first connection pad to the third point is farther than the distance from the first connection pad to the second point.

7. The semiconductor package of claim 1, wherein the thickness of the second terminal region at a first point of the second terminal region is in a range of 90 Å to 190 Å,
wherein the thickness of the second terminal region at a second point of the second terminal region is in a range of 50 Å to 120 Å,
wherein the thickness of the second terminal region at a third point of the second terminal region is in a range of 5 Å to 70 Å,
wherein a distance from the first connection pad to the second point is farther than a distance from the first connection pad to the first point, and
wherein a distance from the first connection pad to the third point is farther than the distance from the first connection pad to the second point.

8. The semiconductor package of claim 1, wherein a thickness of a thickest portion of the second terminal region is 3 times to 10 times a thickness of a thinnest portion of the second terminal region.

9. The semiconductor package of claim 1, wherein the oxidized metal in the second terminal region comprises tin oxide, and
wherein the first terminal region comprises at least one from among tin, silver, and copper.

10. The semiconductor package of claim 1, wherein the first terminal region comprises a terminal metal layer, the terminal metal layer is in contact with the second connection pad and the second terminal region, and
wherein the terminal metal layer comprises at least one from among a nickel-tin (Ni—Sn) alloy, a copper-tin (Cu—Sn) alloy, a gold-tin (Au—Sn) alloy, and a palladium-tin (Pd—Sn) alloy.

11. The semiconductor package of claim 1, wherein the first terminal region is in contact with a portion of the first connection pad, and the second terminal region is in contact with another portion of the first connection pad, and
wherein the first terminal region is in contact with a portion of the second connection pad, and the second terminal region is in contact with another portion of the second connection pad.

12. The semiconductor package of claim 1, wherein the first connection pad comprises a first pad metal layer and a second pad metal layer,
wherein the first terminal region is in contact with the first pad metal layer, and the second terminal region is in contact with the first pad metal layer, and
wherein the first pad metal layer comprises at least one from among gold (Au), nickel (Ni), tin (Sn), lead (Pb), and silver (Ag).

13. The semiconductor package of claim 1, further comprising a conductive pillar between the first connection pad and the connection terminal,
wherein the first terminal region is in contact with a portion of one surface of the conductive pillar, and
the second terminal region is in contact with another portion of the one surface of the conductive pillar.

14. The semiconductor package of claim 1, wherein the second terminal region is formed by performing etching by an etching solution containing fluorine so that a first portion of the second terminal region, has a smaller thickness than a thickness of a second portion of the second terminal region, and
wherein the second portion is closer than the first portion to the first connection pad.

15. A semiconductor package comprising:
a semiconductor device;
a first connection pad on one surface of the semiconductor device; and
a connection terminal at one end of the first connection pad,
wherein the connection terminal comprises a first terminal region and a second terminal region,
wherein the first terminal region is at least partially surrounded by the second terminal region, and
wherein the second terminal region comprises an oxidized metal, and a thickness of the second terminal region varies.

16. The semiconductor package of claim 15, wherein a portion of the first terminal region is in contact with the first connection pad, and another portion of the first terminal region is surrounded by the second terminal region.

17. The semiconductor package of claim 15, wherein the thickness of the second terminal region decreases with an increasing distance from the first connection pad.

18. The semiconductor package of claim 15, wherein a thickness of the second terminal region at a first point of the second terminal region is greater than a thickness of the second terminal region at a second point of the second terminal region,
wherein the thickness of the second terminal region at the second point of the second terminal region is greater than a thickness of the second terminal region at a third point of the second terminal region,
wherein a distance from the first connection pad to the second point is farther than a distance from the first connection pad to the first point, and
wherein a distance from the first connection pad to the third point is farther than a distance from the first connection pad to the second point.

19. The semiconductor package of claim 15, wherein a thickness of the second terminal region at a first point of the second terminal region is in a range of 90 Å to 190 Å,
wherein a thickness of the second terminal region at a second point of the second terminal region is in a range of 50 Å to 120 Å,
wherein a thickness of the second terminal region at a third point of the second terminal region is in a range of 5 Å to 70 Å,
wherein the first point of the second terminal region is adjacent to the first connection pad,
wherein the second point of the second terminal region is at a position corresponding to half a height of the connection terminal, and
wherein the third point of the second terminal region is farther than the first point and the second point from the first connection pad.

20. A semiconductor package comprising:
a semiconductor device;
a first connection pad on one surface of the semiconductor device;
a connection terminal at one end of the first connection pad; and
a second connection pad in contact with the connection terminal,
wherein the connection terminal comprises a solder ball,
wherein the connection terminal is between the first connection pad and the second connection pad,
wherein the solder ball comprises a first terminal region and a second terminal region,
wherein the first terminal region is at least partially surrounded by the second terminal region,
wherein the second terminal region comprises an oxidized metal, and a thickness of the second terminal region varies,
wherein the oxidized metal in the second terminal region comprises tin oxide,
wherein the first terminal region comprises at least one from among tin, silver, and copper,
wherein the first terminal region comprises a terminal metal layer, and the terminal metal layer is in contact with the second connection pad and the second terminal region,
wherein the terminal metal layer comprises at least one from among a nickel-tin (Ni—Sn) alloy, a copper-tin (Cu—Sn) alloy, a gold-tin (Au—Sn) alloy, and a palladium-tin (Pd—Sn) alloy,
wherein the thickness of the second terminal region at a first point of the second terminal region is greater than the thickness of the second terminal region at a second point of the second terminal region,
wherein the thickness of the second terminal region at the second point of the second terminal region is greater than the thickness of the second terminal region at a third point of the second terminal region,
wherein the thickness of the second terminal region at the first point of the second terminal region is in a range of 90 Å to 190 Å,
wherein the thickness of the second terminal region at the second point of the second terminal region is in a range of 50 Å to 120 Å,
wherein the thickness of the second terminal region at the third point of the second terminal region is in a range of 0 Å to 70 Å,
wherein a distance from the first connection pad to the second point is farther than a distance from the first connection pad to the first point,
wherein a distance from the first connection pad to the third point is farther than the distance from the first connection pad to the second point,
wherein a thickness of a thickest portion of the second terminal region is 3 times to 10 times a thickness of a thinnest portion of the second terminal region,
wherein the first terminal region is in contact with a portion of the first connection pad, the second terminal region is in contact with another portion of the first connection pad, the first terminal region is in contact with a portion of the second connection pad, and the second terminal region is in contact with another portion of the second connection pad,
wherein the first connection pad comprises a first pad metal layer and a second pad metal layer,
wherein the first terminal region is in contact with the first pad metal layer, and the second terminal region is in contact with the first pad metal layer, and
wherein the first pad metal layer comprises at least one from gold (Au), nickel (Ni), tin (Sn), lead (Pb), and silver (Ag).
